(19) United States
(12) Patent Application Publication
(10) Pub. No.: US 2026/0262203 A1
(43) Pub. Date: Sep. 3, 2026

(54) CYLINDRICAL BODY FITTING STRUCTURE AND INVERTER

(71) Applicant: ASTEMO, LTD., Chiyoda-ku, Tokyo (JP)

(72) Inventors: Nayuta YAMACHI, Hitachinaka-shi, Ibaraki (JP); Takeshi SEKI, Hitachinaka-shi, Ibaraki (JP); Masahiro UETAKE, Hitachinaka-shi, Ibaraki (JP); Kazushi TAKAHASHI, Hitachinaka-shi, Ibaraki (JP); Ayumu HATANAKA, Hitachinaka-shi, Ibaraki (JP)

(73) Assignee: ASTEMO, LTD., Chiyoda-ku, Tokyo (JP)

(21) Appl. No.: 19/165,435

(22) PCT Filed: Mar. 22, 2023
(86) PCT No.: PCT/JP2023/011300

§ 371 Date: Sep. 15, 2025

(51) Int. Cl. H05K 7/20; H02M 7/00

(52) U.S. Cl. CPC H05K 7/20927; H02M 7/003

(57) ABSTRACT

A cylindrical body fitting structure and an inverter including: a first cylindrical body having a first cylindrical fitting portion that is fitted with another cylindrical body; and a second cylindrical body having a second cylindrical fitting portion that is fitted with the t first cylindrical fitting portion, the first cylindrical body and the second cylindrical body being fitted and connected with each other, wherein at least one of the first cylindrical fitting portion and the second cylindrical fitting portion is provided with a press fitting load release portion that is bent in a radial direction when the first cylindrical fitting portion and the second cylindrical fitting portion are fitted with each other.

### TECHNICAL FIELD

The present invention relates to a cylindrical body fitting structure and an inverter.

### BACKGROUND ART

In power converters, the water passage pipe and the housing are subjected to pressing and fitting between members made of an aluminum material, which requires a fitting structure for which a concern that an airtight defect or a process defect occurs is considered. For example, PTL 1 below discloses that a cooling structure ensures high reliability by taking measures against leakage of the coolant while maintaining miniaturization and weight reduction when the fitted members are made of different materials, an adhesive is used on the press fitting surfaces, and a press fitting jig and a galling prevention jig are used.

### CITATION LIST

### Patent Literature

PTL 1: JP 2021-118616 A

### SUMMARY OF INVENTION

### Technical Problem

In the conventional structures, although the pressing and fitting between members made of the same material ensures airtightness without using an anaerobic adhesive agent at the fitting portion, the press fitting between aluminum materials has caused a concern that the press fitting portions may bite or gall with each other, resulting in an airtight defect or a process defect. In view of this, an object of the present invention is to provide a cylindrical body fitting structure and an inverter that successfully suppress galling during pressing and fitting and reduce airtight defects.

### Solution to Problem

The cylindrical body fitting structure and the inverter according to the present invention include: a first cylindrical body having a first cylindrical fitting portion that is fitted with another cylindrical body; and a second cylindrical body having a second cylindrical fitting portion that is fitted with the first cylindrical fitting portion, the first cylindrical body and the second cylindrical body being fitted and connected with each other, wherein at least one of the first cylindrical fitting portion and the second cylindrical fitting portion is provided with a press fitting load release portion that is bent in a radial direction when the first cylindrical fitting portion and the second cylindrical fitting portion are fitted with each other.

### Advantageous Effects of Invention

According to the present invention, it is possible to provide a cylindrical body fitting structure and an inverter that successfully suppress galling during pressing and fitting and reduce airtight defects.

### BRIEF DESCRIPTION OF DRAWINGS

FIG. 1 is an overall exploded view of a power converter.

FIG. 2 is a view illustrating a step of fitting a water passage pipe according to an embodiment of the present invention.

FIG. 3 is a view illustrating the fitting state of a water passage pipe according to an embodiment of the present invention.

FIG. 4 is a view illustrating a cylindrical body fitting structure according to an embodiment of the present invention.

FIG. 5 shows a first modification.

FIG. 6 shows a second modification.

FIG. 7 shows a third modification.

FIG. 8 shows a fourth modification.

Hereinafter, embodiments of the present invention will be described with reference to the drawings. The following description and drawings are examples for describing the present invention, and are omitted and simplified as appropriate for the sake of clarity of description. The present invention can be carried out in various other forms. Unless otherwise specified, each component may be singular or plural.

The position, size, shape, range, and the like of each component illustrated in the drawings do not necessarily represent the actual position, size, shape, range, and the like in order to facilitate understanding of the invention. Therefore, the present invention is not necessarily limited to the position, size, shape, range, and the like disclosed in the drawings.

### One Embodiment and Overall Configuration of Present Invention

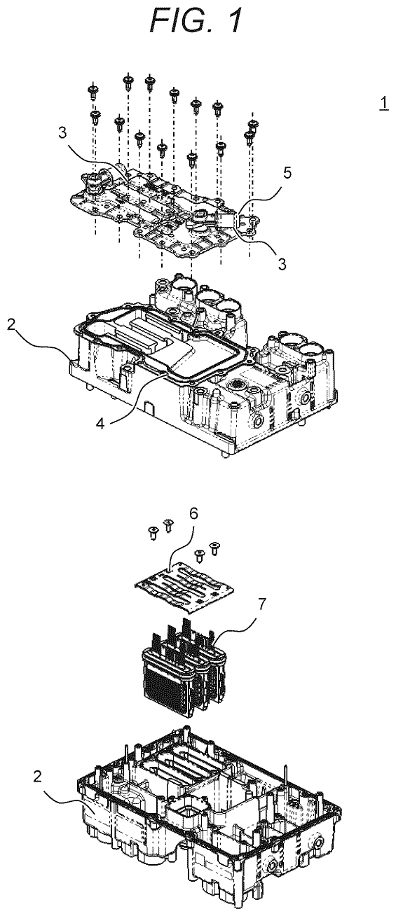

### FIG. 1

A power converter 1 includes a case 2 and a lower cover 5. The case 2 houses a power module 7 having a switching semiconductor element to perform power conversion. The lower cover 5 has a water passage pipe 3. The water passage pipe 3 is press-fitted and connected to the lower cover 5. The water passage pipe 3 and the lower cover 5 are the same metal member formed by aluminum die-casting.

In the portion where a cooling flow path is formed between the case 2 and the lower cover 5, a sealant 4 is applied to the groove of the connection portion between the case 2 and the lower cover 5. The lower cover 5 is attached to sandwich the sealant 4, and is fixed with a bolt, so that the cooling flow path that is formed between the case 2 and the lower cover 5 is sealed. In this way, the entire flow path of the water passage pipe 3 attached to the lower cover 5 becomes a closed space. Therefore, a cooling flow path to connect the case 2 and the water passage pipe 3 is formed, and the refrigerant flowing through the inside thereof cools the entire power converter 1 including the power module 7.

The power module 7 is inserted into the case 2. A power module plate 6 is assembled to the case 2 to hold the inserted power module 7. The power converter 1 is provided with a flow path communicating with a cylindrical body, and housed in the case 2. Inside the flow path formed in the case 2, a refrigerant flows to cool the power module 7.

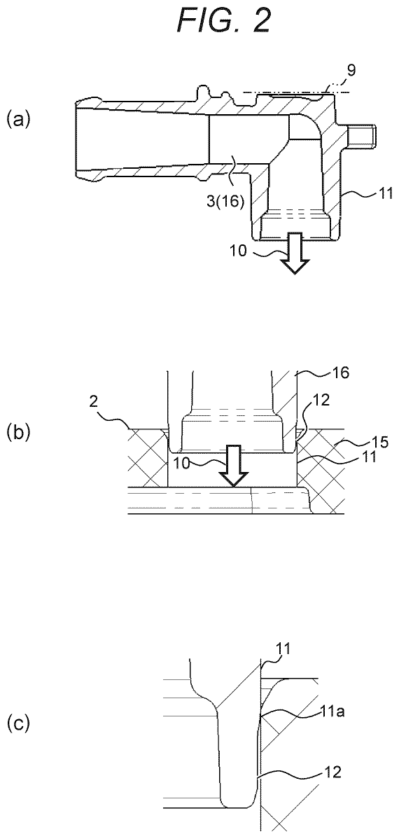

### FIG. 2

FIG. 2(a) is an internal structural view of the water passage pipe 3; FIG. 2(b) is a view illustrating a state in which the water passage pipe 3 is fitted to the case 2; and FIG. 2(c) is a view illustrating a state of the fitting surface. The water passage pipe 3 is applied with a lubricating oil (not illustrated) on a press fitting surface 11 to fit with the case 2, for the purpose of preventing damage during press fitting. Hereinafter, description will be made such that the fitting portion of the case 2 with the water passage pipe 3 is referred to as a first cylindrical body 15, and the water passage pipe 3 is referred to as a second cylindrical body 16.

The second cylindrical body 16 has a surface-pressing portion 9 that is a plane perpendicular to a press fitting direction 10 of the second cylindrical body 16 to the first cylindrical body 15. When the surface-pressing portion 9 is pressed with a press fitting jig (not illustrated), the second cylindrical body 16 moves in the press fitting direction 10 to be fitted with the first cylindrical body 15. Further, press fitting through the surface-pressing portion 9 can suppress a partial contact between the press fitting surface 11 of the second cylindrical body 16 and the first cylindrical body 15. As described above, the press fitting load can be uniformly distributed. Therefore, it is possible to prevent the occurrence of inclination during pressing and fitting and to contribute to suppressing the galling of the press fitting surface 11 and preventing damage of the press fitting surface 11.

At the tip of the second cylindrical body 16, a guide surface 12 having a straight shape is provided. In this manner, the second cylindrical body 16 has an aligning structure to align the centers of the holes of the fitted second cylindrical body 16 and first cylindrical body 15 at the beginning of the press fitting step. In addition, since the guide surface 12 is provided, the cores of the cylindrical fitting portions can be aligned during press fitting to suppress a partial contact of the press fitting surface and uniformly distribute the fitting load, thereby the effect of suppressing damage and galling of the press fitting surface can be obtained.

As shown in FIG. 2(b), as the second cylindrical body 16 is gradually press-fitted while being contacted with the first cylindrical body 15, the contact surface is switched from the guide surface 12 to the press fitting surface 11. In this manner, when the second cylindrical body 16 is press-fitted into the first cylindrical body 15, the portion of the first contact therebetween is a press fitting start portion 11a. That is, the press fitting start portion 11a is the intersection of the guide range and the press fitting range. The press fitting range means a range where the axial diameter of the second cylindrical body 16 is larger than the hole diameter of the first cylindrical body 15. The tip of the second cylindrical body 16 partially expands the inner diameter of the first cylindrical body 15 as being press-fitted into the first cylindrical body 15.

During press fitting, the portion to which the highest stress is applied is the switching portion from the guide surface 12 to the press fitting, the switching portion serving as a starting point of galling. Galling is less likely to occur in the middle of press fitting, and galling usually occurs from the switching point. Therefore, according to the configuration of the present invention, a portion to release the press fitting load is provided to temporarily increase the diameter reduction, thereby successfully decreasing the galling potential.

The second cylindrical body 16 can be deformed such that the tip is bent radially inward based on a fulcrum formed at a position on the back side (the upper side in the drawing) of the press fitting start portion 11a, so that the local stress at the press fitting start portion 11a can be alleviated. The term “bend” as used herein is as follows: the outer shape of the second cylindrical body 16 is larger than the inner diameter of the first cylindrical body 15, and therefore, the press fitting dimension is balanced through the diameter reduction of the second cylindrical body 16 and the diameter increase of the first cylindrical body 15 during press fitting, and thereby a large dimension change occurs from the diameter reduction or the diameter increase. Details of the portion related to the bend will be described later.

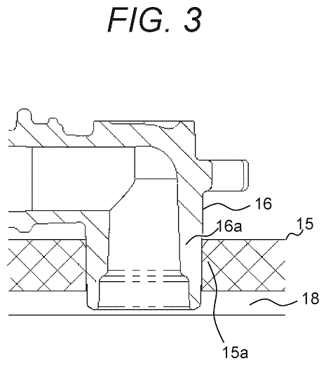

### FIG. 3

The first cylindrical body 15 has a first cylindrical fitting portion 15a that is fitted with the second cylindrical body 16 (or another cylindrical body). The second cylindrical body 16 has a second cylindrical fitting portion 16a that is fitted with the first cylindrical fitting portion 15a. As described above, the second cylindrical fitting portion 16a is press-fitted into the first cylindrical fitting portion 15a so that the second cylindrical body 16 is connected to the flow path 18. In this manner, the cylindrical body fitting structure obtained by fitting and connecting therebetween allows a refrigerant to flow through the entire power converter 1.

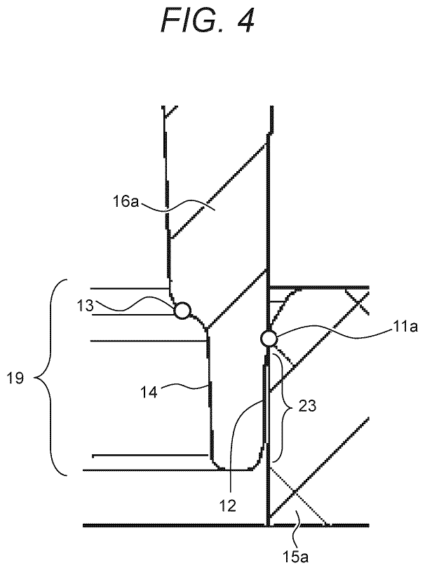

### FIG. 4

In such a fitting structure, the second cylindrical fitting portion 16a is provided with a press fitting load release portion 19 that is bent in a radial direction when the first cylindrical fitting portion 15a and the second cylindrical fitting portion 16a are fitted with each other.

The press fitting load release portion 19 is provided at an end portion of the first cylindrical fitting portion 15a or an end portion of the second cylindrical fitting portion 16a, which face with each other, in a portion where the first cylindrical fitting portion 15a and the second cylindrical fitting portion 16a are fitted with each other. Further, as described above, the press fitting load release portion 19 has a press fitting start portion 11a that is first press-fitted and contacted at a surface where the first cylindrical fitting portion 15a and the second cylindrical fitting portion 16a are fitted and contacted with each other. The press fitting start portion 11a first comes into contact with a minimum inner diameter portion in an inner circumference surface of the first cylindrical fitting portion 15a at an outer circumference portion of the first thinned portion 14 as described later when the first cylindrical fitting portion 15a and the second cylindrical fitting portion 16a are press-fitted and contacted with each other.

The press fitting load release portion 19 has a bend fulcrum portion 13 serving as a fulcrum for bending the first cylindrical fitting portion 15a or the second cylindrical fitting portion 16a in the radial direction when the first cylindrical fitting portion 15a and the second cylindrical fitting portion 16a are fitted with each other. The bend fulcrum portion 13 is determined by providing the first thinned portion 14 as described later, and is positioned and provided on the reverse side of the press fitting direction side of the press fitting start portion 11a when seen from the second cylindrical body 16. This allows deformation when the first cylindrical fitting portion 15a and the second cylindrical fitting portion 16a are pressed and fitted with each other, and the end portion of the second cylindrical fitting portion 16a is bent radially inward, thereby obtaining an effect of alleviating the stress during fitting. In addition, management in the mass production process becomes easy, and this also contributes to improving yield in terms of defective press fitting.

The press fitting load release portion 19 has a first thinned portion 14 on a side of the second cylindrical fitting portion 16a in a portion where the first cylindrical fitting portion 15a and the second cylindrical fitting portion 16a are fitted with each other. The entire thickness of the water passage pipe 3 including the second cylindrical body 16 is a thickness necessary for molding by die casting. However, the first thinned portion 14 in the vicinity of the tip of the press fitting portion is formed to be thinner than the standard thickness. Such a configuration can contribute to stabilizing and ensuring the airtight performance without damage on the press fitting surface, and improving the yield. In addition, after completion of the press fitting, the airtightness does not change because the press fitting length is equal after press fitting, which contributes to improved reliability.

As described above, the first cylindrical body 15 and the second cylindrical body 16 are formed of the same material. As a result, there is no linear expansion difference when the members are thermally affected, and the state of the press fitting surfaces can be made constant when the members are connected to each other, so that reliability can be improved. In addition, since the first cylindrical body 15 and the second cylindrical body 162 are made of the same material, the press fitting surfaces do not separate from each other due to temperature change, so that the airtightness is not affected. In addition, it is not necessary to use an anaerobic adhesive agent, which causes a risk of airtight defects due to deterioration over time when used at the press fitting surface, and high durability performance is obtained. In addition, this can also contribute to supporting clients who wish to use no adhesive agent in water path portions.

The bend fulcrum portion 13 is formed at the R-end portion of the first thinned portion 14. The thinned region of the first thinned portion 14 is not limited, and is formed such that the thinned region is bent in response to a press fitting load determined from the necessary airtight characteristics. In this way, it is possible to alleviate the local stress at the press fitting start point and to prevent the surface from being damaged or curled.

The first thinned portion 14 has the guide surface 12 described above on a press fitting side of the second cylindrical body 16, as compared with the press fitting start portion 11a, in an outer circumference surface. The guide surface 12 has a cylindrical surface parallel to a press fitting direction of the second cylindrical body 16. In this manner, since the range of the guide surface 12 at the tip of the second cylindrical body 16 has a straight shape, the length of the guide, which is a surface to first come into contact therewith during press fitting, can be widely formed, so that the centering accuracy is improved during press fitting.

### First Modification

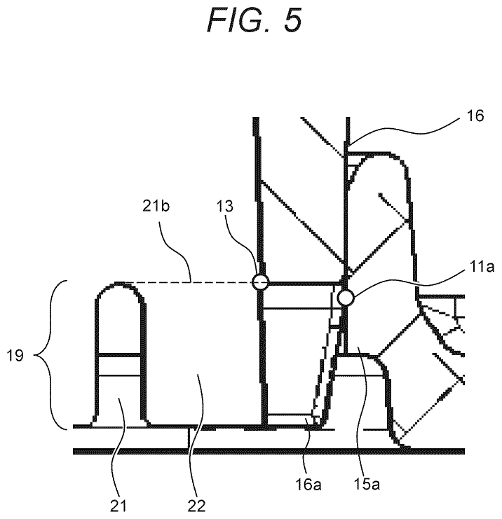

### FIG. 5

As the press fitting load release portion 19, the end portion of the second cylindrical body 16 is cut out from an insertion tip portion of the second cylindrical fitting portion 16a toward a reverse side of an insertion direction; and has at least three cut-out portions 21 arranged at equal intervals in a circumferential direction of the end portion, and at least three peripheral wall portions 22 adjacent to each other in the circumferential direction between the cut-out portions 21. Note that the cut-out portion 21 and the peripheral wall portion 22 are illustrated one by one for the convenience of the cross-sectional view of the drawing.

The press fitting start portion 11a first comes into contact with a minimum inner diameter portion in an inner circumference surface of the first cylindrical fitting portion 15a at an outer circumference portion of the cut-out portions 21 when the first cylindrical fitting portion 15a and the second cylindrical fitting portion 16a are press-fitted and contacted with each other.

The bend fulcrum portion 13 is formed on a reverse side of a press fitting side of the second cylindrical body 16, as compared with the press fitting start portion 11a, in an inner circumference portion of the cut-out portions 21; and supports a radially inward bend of the second cylindrical body 16 when the first cylindrical fitting portion 15a and the second cylindrical fitting portion 16a are contacted with each other.

In order to bend the second cylindrical body 16, a cut-out apex 21b (bend fulcrum portion 13) needs to be provided on the back side of the press fitting start portion 11a in the press fitting direction. Note that the cut-out shape of the cut-out portion 21 is not limited.

Accordingly, similarly to the embodiment described with reference to FIG. 4, the radially inward diameter reduction of the cut-out portion 21 can alleviate stress concentration when the second cylindrical body 16 is press-fitted into the first cylindrical body 15. In addition, since the surface pressure after press fitting is substantially unchanged, there is an advantage that there is no adverse effect on airtightness. In addition, when three or more cut-out portions 21 are provided, the deformation in the circumferential direction is hardly biased as compared with the case when two or less cut-outs are provided, so that the peripheral wall portions 22 are evenly deformed as a whole. In addition, the cut-out portion 21 is advantageous in that there is no need to reduce the thickness of the guide surface 12.

### Second Modification

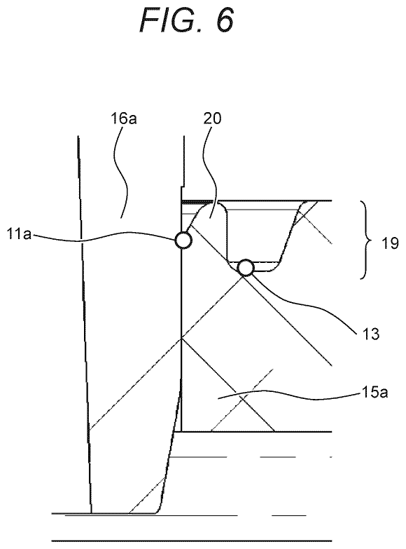

### FIG. 6

The press fitting load release portion 19 has a second thinned portion 20 on a side of the first cylindrical fitting portion in a portion where the first cylindrical fitting portion 15a and the second cylindrical fitting portion 16a are fitted with each other. The press fitting start portion 11a first comes into contact with a maximum outer diameter portion in an outer circumference surface of the second cylindrical fitting portion 16a at an inner circumference portion of the second thinned portion 20 when the first cylindrical fitting portion 15a and the second cylindrical fitting portion 16a are press-fitted and contacted with each other.

The bend fulcrum portion 13 is formed on a reverse side of a press fitting side of the second cylindrical body 16, as compared with the press fitting start portion 11a, in an outer circumference portion of the second thinned portion 20; and supports a radially outward bend of the first cylindrical body 15 when the first cylindrical fitting portion 15a and the second cylindrical fitting portion 16a are contacted with each other.

As described above, when a groove is formed to provide the second thinned portion 20 radially outward at the end portion of the side of the first cylindrical body 15 as the press fitting load release portion 19, and the depth of the groove is slightly deeper than that of the press fitting start portion 11a, the bend fulcrum portion 13 is provided on the press fitting direction side of the press fitting start portion 11a. As a result, the diameter increase of the first cylindrical body 15 can alleviate stress concentration during press fitting; and there is no influence of airtightness since the surface pressure after press fitting is substantially unchanged.

### Third Modification

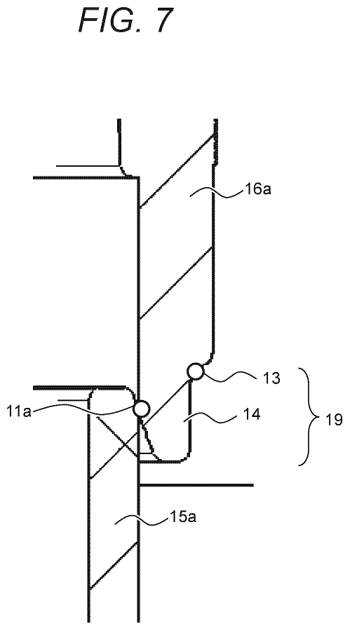

### FIG. 7

The press fitting load release portion 19 has a first thinned portion 14 on the outer circumference side of the second cylindrical fitting portion 16a in a portion where the first cylindrical fitting portion 15a and the second cylindrical fitting portion 16a are fitted with each other. The press fitting start portion 11a first comes into contact with a maximum outer diameter portion in an outer circumference surface of the first cylindrical fitting portion 15a at an inner circumference portion of the first thinned portion 14 when the first cylindrical fitting portion 15a and the second cylindrical fitting portion 16a are press-fitted and contacted with each other.

The bend fulcrum portion 13 is formed on a reverse side of a press fitting side of the second cylindrical body 16, as compared with the press fitting start portion 11a, in an outer circumference portion of the first thinned portion 14; and supports a radially outward bend of the second cylindrical body 16 when the first cylindrical fitting portion 15a and the second cylindrical fitting portion 16a are contacted with each other. In this manner, in the case of a structure in which the outer shape of the first cylindrical body 15 is fitted to the inner diameter side of the second cylindrical body 16, it is possible to constantly secure the flow path cross-sectional area and alleviate the stress during press fitting.

### Fourth Modification

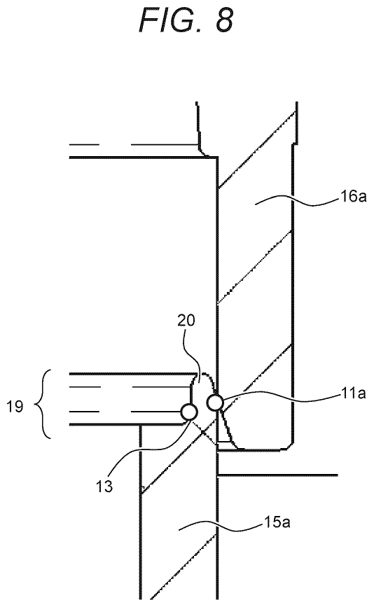

### FIG. 8

The press fitting load release portion 19 has a second thinned portion 20 on a side of the first cylindrical fitting portion 15a in a portion where the first cylindrical fitting portion 15a and the second cylindrical fitting portion 16a are fitted with each other. The press fitting start portion 11a first comes into contact with a minimum inner diameter portion in an inner circumference surface of the second cylindrical fitting portion 16a at an outer circumference portion of the second thinned portion 20 when the first cylindrical fitting portion 15a and the second cylindrical fitting portion 16a are press-fitted and contacted with each other. The bend fulcrum portion 13 is formed on a press fitting side of the second cylindrical body 16, as compared with the press fitting start portion 11a, in an inner circumference portion of the second thinned portion 20; and supports a radially inward bent of the first cylindrical body 15 when the first cylindrical fitting portion 15a and the second cylindrical fitting portion 16a are contacted with each other.

Thereby, in the case of a structure in which the outer shape of the first cylindrical body 15 is fitted to the inner diameter side of the second cylindrical body 16, it is possible to constantly secure the flow path cross-sectional area and alleviate the stress during press fitting, as described in FIG. 7.

Although the configuration of the present invention has been described above, the bend fulcrum portion 13 may be provided on both the first cylindrical body 15 side and the second cylindrical body 16 side. When the press fitting load release portion 19 is provided on both the first cylindrical body 15 and the second cylindrical body 16 by combining both the configurations as described above, not only the local stress during press fitting is load-released by bending, but also the deformation can be made with a small load so that the operational effects as described above are further improved.

According to the embodiments of the present invention described above, the following operational effects are obtained.
(1) The cylindrical body fitting structure according to the present invention includes: a first cylindrical body 15 having a first cylindrical fitting portion 15a that is fitted with another cylindrical body; and a second cylindrical body 16 having a second cylindrical fitting portion 16a that is fitted with the first cylindrical fitting portion 15a, the first cylindrical body 15 and the second cylindrical body 16 being fitted and connected with each other. At least one of the first cylindrical fitting portion 15a and the second cylindrical fitting portion 16a is provided with a press fitting load release portion 19 that is bent in a radial direction when the first cylindrical fitting portion 15a and the second cylindrical fitting portion 16a are fitted with each other. Thereby, it is possible to provide a cylindrical body fitting structure that successfully suppresses galling during pressing and fitting and reduces airtight defects.
(2) In at least one of the first cylindrical fitting portion 15a and the second cylindrical fitting portion 16a, the press fitting load release portion 19 has a thinned portion 14 or 20 that is bent in the radial direction when the first cylindrical fitting portion 15a and the second cylindrical fitting portion 16a are fitted with each other. The thinned portions 14 and 20 include a bend fulcrum portion 13 serving as a fulcrum for bending in the radial direction. Thereby, the press fitting load can be uniformly distributed. Therefore, it is possible to prevent the occurrence of inclination during pressing and fitting.
(3) The press fitting load release portion 19 is provided at an end portion of the first cylindrical fitting portion 15a or an end portion of the second cylindrical fitting portion 16a, which face with each other, in a portion where the first cylindrical fitting portion 15a and the second cylindrical fitting portion 16a are fitted with each other; and has a press fitting start portion 11a that is first press-fitted and contacted at a surface where the first cylindrical fitting portion 15a and the second cylindrical fitting portion 16a are fitted and contacted with each other. The bend fulcrum portion 13 is positioned on a press fitting direction 10 side of the press fitting start portion 11a when seen from the first cylindrical body 15, and is positioned on a reverse side of the press fitting direction 10 side of the press fitting start portion 11a when seen from the second cylindrical body 16; and an end portion of the first cylindrical fitting portion 15a is bent radially outward, and an end portion of the second cylindrical fitting portion 166a is bent radially inward when the first cylindrical fitting portion 15a and the second cylindrical fitting portion 16a are fitted with each other. This contributes to suppressing the galling of the press fitting surface 11 and to preventing damage of the press fitting surface 11.
(4) The press fitting load release portion 19 has a first thinned portion 14 on a side of the second cylindrical fitting portion 16a in a portion where the first cylindrical fitting portion 15a and the second cylindrical fitting portion 16a are fitted with each other. The press fitting start portion 11a first comes into contact with a minimum inner diameter portion in an inner circumference surface of the first cylindrical fitting portion 15a at an outer circumference portion of the first thinned portion 14 when the first cylindrical fitting portion 15a and the second cylindrical fitting portion 16a are press-fitted and contacted with each other. The bend fulcrum portion 13 is formed on a reverse side of a press fitting side of the second cylindrical body 16, as compared with the press fitting start portion 11a, in an inner circumference portion of the first thinned portion 14; and supports a radially inward bend of the second cylindrical body 16 when the first cylindrical fitting portion 15a and the second cylindrical fitting portion 16a are contacted with each other. In this manner, the second cylindrical body 16 on the press fitting side mainly obtains the effect of alleviating stress during fitting.
(5) The end portion of the second cylindrical body 16 is cut out from an insertion tip portion of the second cylindrical fitting portion 16a toward a reverse side of an insertion direction; and has at least three cut-out portions 21 arranged at equal intervals in a circumferential direction of the end portion, and at least three peripheral wall portions 22 adjacent to each other in the circumferential direction between the cut-out portions 21. The press fitting start portion 11a first comes into contact with a minimum inner diameter portion in an inner circumference surface of the first cylindrical fitting portion 15a at an outer circumference portion of the cut-out portions 21 when the first cylindrical fitting portion 15a and the second cylindrical fitting portion 16a are press-fitted and contacted with each other. The bend fulcrum portion 13 is formed on a reverse side of a press fitting side of the second cylindrical body 16, as compared with the press fitting start portion 11a, in an inner circumference portion of the cut-out portions 21; and supports a radially inward bend of the second cylindrical body 16 when the first cylindrical fitting portion 15a and the second cylindrical fitting portion 16a are contacted with each other. In this manner, the second cylindrical body 16 on the press fitting side, even having an end portion in another embodiment, mainly obtains the effect of alleviating stress during fitting.
(6) The press fitting load release portion 19 has a second thinned portion 20 on a side of the first cylindrical fitting portion 15a in a portion where the first cylindrical fitting portion 15a and the second cylindrical fitting portion 16a are fitted with each other. The press fitting start portion 11a first comes into contact with a maximum outer diameter portion in an outer circumference surface of the second cylindrical fitting portion 16a at an inner circumference portion of the second thinned portion 20 when the first cylindrical fitting portion 15a and the second cylindrical fitting portion 16a are press-fitted and contacted with each other. The bend fulcrum portion 13 is formed on a reverse side of a press fitting side of the second cylindrical body 16, as compared with the press fitting start portion 11a, in an outer circumference portion of the second thinned portion 20; and supports a radially outward bend of the first cylindrical body 15 when the first cylindrical fitting portion 15a and the second cylindrical fitting portion 16a are contacted with each other. In this manner, the first cylindrical body 15 on the press-fitted side mainly obtains the effect of alleviating stress during fitting.
(7) The press fitting load release portion 19 has a first thinned portion 14 on a side of the second cylindrical fitting portion 16a in a portion where the first cylindrical fitting portion 15a and the second cylindrical fitting portion 16a are fitted with each other. The press fitting start portion 11a first comes into contact with a maximum outer diameter portion in an outer circumference surface of the first cylindrical fitting portion 15a at an inner circumference portion of the first thinned portion 14 when the first cylindrical fitting portion 15a and the second cylindrical fitting portion 16a are press-fitted and contacted with each other. The bend fulcrum portion 13 is formed on a reverse side of a press fitting side of the second cylindrical body 16, as compared with the press fitting start portion 11a, in an outer circumference portion of the first thinned portion 14; and supports a radially outward bend of the second cylindrical body 16 when the first cylindrical fitting portion 15a and the second cylindrical fitting portion 16a are contacted with each other. In this manner, even when the second cylindrical body 16 is fitted into a convex cylindrical body as the first cylindrical body 15, the second cylindrical body 16 on the press fitting side mainly obtains the effect of alleviating stress during fitting.
(8) The press fitting load release portion 19 has a second thinned portion 20 on a side of the first cylindrical fitting portion 15a in a portion where the first cylindrical fitting portion 15a and the second cylindrical fitting portion 16a are fitted with each other. The press fitting start portion 11a first comes into contact with a minimum inner diameter portion in an inner circumference surface of the second cylindrical fitting portion 16a at an outer circumference portion of the second thinned portion 20 when the first cylindrical fitting portion 15a and the second cylindrical fitting portion 16a are press-fitted and contacted with each other. The bend fulcrum portion 13 is formed on a press fitting side of the second cylindrical body 16, as compared with the press fitting start portion 11a, in an inner circumference portion of the second thinned portion 20; and supports a radially inward bent of the first cylindrical body 15 when the first cylindrical fitting portion 15a and the second cylindrical fitting portion 16a are contacted with each other. In this manner, even when the second cylindrical body 16 is fitted into a convex cylindrical body as the first cylindrical body 15, the first cylindrical body 15 on the press-fitted side mainly obtains the effect of alleviating stress during fitting.
(9) The first thinned portion 14 has a guide surface 12 on a press fitting side of the second cylindrical body 16, as compared with the press fitting start portion 11a, in an outer circumference surface; and the guide surface 12 has a cylindrical surface parallel to a press fitting direction of the second cylindrical body 16. Thereby, the centering accuracy is improved during press fitting.
(10) The first cylindrical body 15 and the second cylindrical body 16 are made of a same material. Thereby, connection reliability is improved.
(11) The second cylindrical body 16 has a surface-pressing portion 9 that is a plane perpendicular to a press fitting direction of the second cylindrical body 16. Thereby, partial contact during press fitting can be suppressed.
(12) A power converter 1 includes: a housing 2 having a flow path 18 communicating with the first cylindrical body 15 and the second cylindrical body 16; and a power module 7 that is housed in the housing 2 and has a switching semiconductor element to perform power conversion. Inside the flow path 18, a refrigerant flows to cool the power module 7. Thereby, it is possible to provide a power converter 1 having a cylindrical body fitting structure that successfully suppresses galling during pressing and fitting and reduces airtight defects.

Note that the present invention is not limited to the above embodiments, and various modifications and other configurations can be combined without departing from the gist of the present invention. In addition, the present invention is not limited to one including all the configurations described in the above embodiments, and includes one in which a part of the configurations is deleted.

### REFERENCE SIGNS LIST

1 power converter
2 case
3 water passage pipe
4 sealant
5 lower cover
6 power module plate
7 power module
9 surface-pressing portion
10 press fitting direction
11 press fitting surface
11a press fitting start portion
12 guide surface
13 bend fulcrum portion
14 first thinned portion
15 first cylindrical body
15a first cylindrical fitting portion
16 second cylindrical body
16a second cylindrical fitting portion
18 flow path
19 press fitting load release portion
20 second thinned portion
21 cut-out portion
21b cut-out apex
22 peripheral wall portion
23 cylindrical surface

1. A cylindrical body fitting structure comprising:
a first cylindrical body having a first cylindrical fitting portion that is fitted with another cylindrical body; and
a second cylindrical body having a second cylindrical fitting portion that is fitted with the first cylindrical fitting portion,
the first cylindrical body and the second cylindrical body being fitted and connected with each other,
wherein at least one of the first cylindrical fitting portion and the second cylindrical fitting portion is provided with a press fitting load release portion that is bent in a radial direction when the first cylindrical fitting portion and the second cylindrical fitting portion are fitted with each other.

2. The cylindrical body fitting structure according to claim 1, wherein
in at least one of the first cylindrical fitting portion and the second cylindrical fitting portion, the press fitting load release portion has a thinned portion that is bent in the radial direction when the first cylindrical fitting portion and the second cylindrical fitting portion are fitted with each other; and
the thinned portion includes a bend fulcrum portion serving as a fulcrum for bending in the radial direction.

3. The cylindrical body fitting structure according to claim 2, wherein
the press fitting load release portion is provided at an end portion of the first cylindrical fitting portion or an end portion of the second cylindrical fitting portion, which face with each other, in a portion where the first cylindrical fitting portion and the second cylindrical fitting portion are fitted with each other; and has a press fitting start portion that is first press-fitted and contacted at a surface where the first cylindrical fitting portion and the second cylindrical fitting portion are fitted and contacted with each other; and
the bend fulcrum portion is positioned on a press fitting direction side of the press fitting start portion when seen from the first cylindrical body, and is positioned on a reverse side of the press fitting direction side of the press fitting start portion when seen from the second cylindrical body; and an end portion of the first cylindrical fitting portion is bent radially outward, and an end portion of the second cylindrical fitting portion is bent radially inward when the first cylindrical fitting portion and the second cylindrical fitting portion are fitted with each other.

4. The cylindrical body fitting structure according to claim 3, wherein
the press fitting load release portion has a first thinned portion on a side of the second cylindrical fitting portion in a portion where the first cylindrical fitting portion and the second cylindrical fitting portion are fitted with each other;
the press fitting start portion first comes into contact with a minimum inner diameter portion in an inner circumference surface of the first cylindrical fitting portion at an outer circumference portion of the first thinned portion when the first cylindrical fitting portion and the second cylindrical fitting portion are press-fitted and contacted with each other; and
the bend fulcrum portion is formed on a reverse side of a press fitting side of the second cylindrical body, as compared with the press fitting start portion, in an inner circumference portion of the first thinned portion; and supports a radially inward bend of the second cylindrical body when the first cylindrical fitting portion and the second cylindrical fitting portion are contacted with each other.

5. The cylindrical body fitting structure according to claim 3, wherein an end portion of the second cylindrical body is cut out from an insertion tip portion of the second cylindrical fitting portion toward a reverse side of an insertion direction; and has at least three cut-out portions arranged at equal intervals in a circumferential direction of the end portion, and at least three peripheral wall portions adjacent to each other in the circumferential direction between the cut-out portions;
the press fitting start portion first comes into contact with a minimum inner diameter portion in an inner circumference surface of the first cylindrical fitting portion at an outer circumference portion of the cut-out portions when the first cylindrical fitting portion and the second cylindrical fitting portion are press-fitted and contacted with each other; and
the bend fulcrum portion is formed on a reverse side of a press fitting side of the second cylindrical body, as compared with the press fitting start portion, in an inner circumference portion of the cut-out portions; and supports a radially inward bend of the second cylindrical body when the first cylindrical fitting portion and the second cylindrical fitting portion are contacted with each other.

6. The cylindrical body fitting structure according to claim 3, wherein
the press fitting load release portion has a second thinned portion on a side of the first cylindrical fitting portion in a portion where the first cylindrical fitting portion and the second cylindrical fitting portion are fitted with each other;
the press fitting start portion first comes into contact with a maximum outer diameter portion in an outer circumference surface of the second cylindrical fitting portion at an inner circumference portion of the second thinned portion when the first cylindrical fitting portion and the second cylindrical fitting portion are press-fitted and contacted with each other; and
the bend fulcrum portion is formed on a reverse side of a press fitting side of the second cylindrical body, as compared with the press fitting start portion, in an outer circumference portion of the second thinned portion; and supports a radially outward bend of the first cylindrical body when the first cylindrical fitting portion and the second cylindrical fitting portion are contacted with each other.

7. The cylindrical body fitting structure according to claim 3, wherein
the press fitting load release portion has a first thinned portion on a side of the second cylindrical fitting portion in a portion where the first cylindrical fitting portion and the second cylindrical fitting portion are fitted with each other;
the press fitting start portion first comes into contact with a maximum outer diameter portion in an outer circumference surface of the first cylindrical fitting portion at an inner circumference portion of the first thinned portion when the first cylindrical fitting portion and the second cylindrical fitting portion are press-fitted and contacted with each other; and
the bend fulcrum portion is formed on a reverse side of a press fitting side of the second cylindrical body, as compared with the press fitting start portion, in an outer circumference portion of the first thinned portion; and supports a radially outward bend of the second cylindrical body when the first cylindrical fitting portion and the second cylindrical fitting portion are contacted with each other.

8. The cylindrical body fitting structure according to claim 3, wherein
the press fitting load release portion has a second thinned portion on a side of the first cylindrical fitting portion in a portion where the first cylindrical fitting portion and the second cylindrical fitting portion are fitted with each other;
the press fitting start portion first comes into contact with a minimum inner diameter portion in an inner circumference surface of the second cylindrical fitting portion at an outer circumference portion of the second thinned portion when the first cylindrical fitting portion and the second cylindrical fitting portion are press-fitted and contacted with each other; and
the bend fulcrum portion is formed on a press fitting side of the second cylindrical body, as compared with the press fitting start portion, in an inner circumference portion of the second thinned portion; and supports a radially inward bent of the first cylindrical body when the first cylindrical fitting portion and the second cylindrical fitting portion are contacted with each other.

9. The cylindrical body fitting structure according to claim 4, wherein
the first thinned portion has a guide surface on a press fitting side of the second cylindrical body, as compared with the press fitting start portion, in an outer circumference surface; and
the guide surface has a cylindrical surface parallel to a press fitting direction of the second cylindrical body.

10. The cylindrical body fitting structure according to claim 1, wherein the first cylindrical body and the second cylindrical body are made of a same material.

11. The cylindrical body fitting structure according to claim 10, wherein the second cylindrical body has a surface-pressing portion that is a plane perpendicular to a press fitting direction of the second cylindrical body.

12. An inverter comprising:
the cylindrical body fitting structure according to claim 1;
a housing having a flow path communicating with the first cylindrical body and the second cylindrical body; and
a power module that is housed in the housing and has a switching semiconductor element to perform power conversion,
wherein, inside the flow path, a refrigerant flows to cool the power module.
